(19) United States
(12) Patent Application Publication
(10) Pub. No.: US 2026/0113904 A1
(43) Pub. Date: Apr. 23, 2026

(54) SYSTEM INTERVENTIONS FOR A COOLANT DISTRIBUTION UNIT

(71) Applicant: LTI Holdings, Inc., Pleasanton, CA (US)

(72) Inventors: Sukhvinder Kang, Pleasanton, CA (US); John R. Durbin, Spotsylvania, VA (US)

(21) Appl. No.: 19/361,852

(22) Filed: Oct. 17, 2025

Related U.S. Application Data
(60) Provisional application No. 63/709,228, filed on Oct. 18, 2024.

(51) Int. Cl. H05K 7/20; C02F 1/68

(52) U.S. Cl. CPC H05K 7/20836; C02F 1/685; H05K 7/20272; H05K 7/20763; C02F 2209/22; C02F 2209/36; C02F 2303/20; C02F 2303/22

(57) ABSTRACT

A system and method of monitoring water quality of a coolant distribution system, by measuring, via a sensor, water within a pipe of the coolant distribution system. The method includes generating, via the sensor, data indicating a quality of the water within the pipe. The method includes determining, via an electronic processor, that the quality of the water within the pipe is below a predetermined threshold. The method includes controlling, via the electronic processor, an injection system to inject an additive solution to the water in the pipe in response to the quality of the water within the pipe being below the predetermine threshold.

### CROSS-REFERENCE TO RELATED APPLICATIONS

This application claims priority to U.S. Provisional Patent Application No. 63/709,228, filed on Oct. 18, 2024, the entire content of which is incorporated herein by reference.

### BACKGROUND

The present invention relates to system interventions for coolant distribution units.

### SUMMARY

A coolant distribution unit (CDU) is a critical component in cooling systems, such as those that operate within data centers, and is designed to efficiently circulate liquid coolant through a network of pipes to remove heat from servers and other information technology (IT) equipment. The primary function of a CDU is to maintain a consistent flow of chilled liquid, such as, for example, water or a water-based solution, to absorb heat generated by the operating hardware. As the coolant circulates through the data center, it absorbs heat from the servers and other equipment. This warmed coolant then returns to the CDU, where it may pass through a heat exchanger to transfer the absorbed heat to a secondary cooling system. In many cases, this secondary system is connected to the building's central cooling plant, which might use chillers or cooling towers to dissipate the heat.

In some instances, data centers incorporate an external heat exchange device located outside the main building. This external unit can serve multiple purposes, such as improving energy efficiency or enabling heat recovery. For example, in colder climates, the external heat exchanger might use the cool outdoor air to chill the returning coolant, reducing the load on mechanical cooling systems. Alternatively, in some applications, the excess heat may be captured and repurposed for heating nearby buildings or other industrial processes.

CDU's may be subject to fault conditions, such as, for example, water quality or pipe leaks. For example, water quality may be compromised by biological material and mineral elements over time. Microorganisms such as bacteria and algae can proliferate in the coolant system, forming biofilms that reduce heat transfer efficiency and potentially clog small passages in heat exchangers or server cooling plates. Mineral elements, such as, for example, calcium, magnesium, copper sulfate, silver sulfate, and the like, can lead to scale formation on pipe walls and heat exchange surfaces. This scaling not only decreases the system's thermal efficiency but can also restrict coolant flow. Additionally, dissolved minerals may cause corrosion in metal components, leading to the formation of metal oxides that can circulate in the system and damage sensitive equipment. These water quality issues can ultimately result in reduced cooling performance, increased energy consumption, higher risk of system failure, or costly maintenance and equipment replacement.

Another such fault condition is a leak in the pipe network of the coolant system. A leak can have severe negative impacts on coolant flow and overall system performance. Even a small leak may lead to a gradual loss of coolant volume, reducing the system's ability to maintain proper pressure and flow rates. This can result in inadequate cooling for certain areas of the data center, potentially causing hotspots and increasing the risk of equipment overheating. Larger leaks may cause sudden pressure drops, triggering emergency shutdowns of cooling systems to prevent pump damage. In addition to compromising cooling efficiency, leaks may also introduce air into the system, leading to air pockets that disrupt coolant flow and reduce heat transfer effectiveness. Furthermore, if the leak occurs in an area where electrical equipment is present, it poses a significant risk of short circuits and equipment damage. The introduction of contaminants through the leak point can also degrade water quality, as previously described, exacerbating the issues mentioned in the previous paragraph.

Accordingly, described herein are systems and methods to address and preempt possible fault conditions, allowing for a more effective and efficient use of the CDU.

In some aspects, the techniques described herein relate to a method of monitoring water quality of a coolant distribution system, the method including measuring, via a sensor, water within a pipe of the coolant distribution system. The method further includes generating, via the sensor, data indicating a quality of the water within the pipe, determining, via an electronic processor, that the quality of the water within the pipe is below a predetermined threshold, and controlling, via the electronic processor, an injection system to inject an additive solution to the water in the pipe in response to the quality of the water within the pipe being below the predetermine threshold.

In some aspects the quality of the water within the pipe includes a measurement of biological material within the water. In some aspects, the additive solution includes a biocide configured to reduce the biological material within the water.

In some aspects, the quality of the water within the pipe includes a measurement of minerals within the water. In some aspects, the additive solution includes a chemical configured to reduce a buildup of minerals within the water.

In some aspects, the techniques described herein relate to a method of controlling a coolant distribution system, the method including measuring, via a sensor, a fluid pressure within a pipe of the coolant distribution system, generating, via the sensor, data indicating a pressure level within the pipe; determining, via an electronic processor, that the pressure level within the pipe is below a predetermined threshold, disconnecting, via the electronic processor, the pipe from a pipe network in response to the pressure level being below the predetermined threshold, and controlling, via the electronic processor, a valve of a vacuum tank to generate a negative pressure within the pipe.

In some aspects, the techniques described herein relate to a method of controlling a coolant distribution system connected to a pipe network, the method including: measuring, via a sensor, a coolant leak condition of the coolant distribution system; generating, via the sensor, data indicating the coolant leak condition; determining, via an electronic processor, that a coolant leak exists within the pipe network in response to the data; controlling, via an electronic processor, one or more components of the pipe network.

In some aspects, the present disclosure relates to a coolant distribution unit including: a housing; a pipe network at least partially supported in the housing and configured to convey a coolant, the pipe network including one or more leak detection sensors configured to measure a coolant leak condition; an injection system fluidly coupled to the pipe network, the injection system configured to inject an additive solution to the coolant in the pipe; and an electronic processor supported in the housing and configured to control operation of one or more elements of the pipe network, wherein the electronic processor is configured to determine whether a leak has occurred in a pipe of the pipe network, and wherein the electronic processor is configured to determine a quality of a coolant with the pipe network and control the injection system to inject an additive solution.

Other aspects of the invention will become apparent by consideration of the detailed description and accompanying drawings.

### BRIEF DESCRIPTION OF THE DRAWINGS

FIG. 1 is an illustration of a coolant distribution unit.

FIG. 2 is an illustration of elements of the coolant distribution unit of FIG. 1.

FIG. 3 is an illustration of elements of the coolant distribution unit of FIG. 1.

FIG. 4 is a system diagram of the coolant distribution unit of FIG. 1.

FIG. 5 is an illustration of the coolant distribution system in combination with a data center.

FIG. 6 is a flow chart of a process of measuring water quality of the coolant distribution unit.

FIG. 7 is a flow chart of a process of responding to system events within the coolant distribution unit.

### DETAILED DESCRIPTION

The scope and applicability of the invention detailed below extends beyond the specific construction details, component arrangements, and implementation methods described or depicted herein. It should be understood that the invention can be realized through various alternative embodiments, execution approaches, and practical applications not limited to those explicitly outlined in the subsequent description or accompanying illustrations.

Before any embodiments are explained in detail, it is to be understood that the embodiments are not limited in their application to the details of the configuration and arrangement of components set forth in the following description or illustrated in the accompanying drawings. The embodiments are capable of being practiced or of being carried out in various ways. Also, it is to be understood that the phraseology and terminology used herein are for the purpose of description and should not be regarded as limiting. The use of “including,” “comprising,” or “having” and variations thereof are meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings.

In addition, it should be understood that embodiments may include hardware, software, and electronic components or modules that, for purposes of discussion, may be illustrated and described as if the majority of the components were implemented solely in hardware. However, one of ordinary skill in the art, and based on a reading of this detailed description, would recognize that, in at least one embodiment, the electronic-based aspects may be implemented in software (e.g., stored on non-transitory computer-readable medium) executable by one or more processing units, such as a microprocessor and/or application specific integrated circuits (“ASICs”). As such, it should be noted that a plurality of hardware and software-based devices, as well as a plurality of different structural components, may be utilized to implement the embodiments. For example, “servers,” “computing devices,” “controllers,” “processors,” etc., described in the specification can include one or more processing units, one or more computer-readable medium modules, one or more input/output interfaces, and various connections (e.g., a system bus) connecting the components.

Relative terminology, such as, for example, “about,” “approximately,” “substantially,” etc., used in connection with a quantity or condition would be understood by those of ordinary skill to be inclusive of the stated value and has the meaning dictated by the context (e.g., the term includes at least the degree of error associated with the measurement accuracy, tolerances [e.g., manufacturing, assembly, use, etc.] associated with the particular value, etc.). Such terminology should also be considered as disclosing the range defined by the absolute values of the two endpoints. For example, the expression “from about 2 to about 4” also discloses the range “from 2 to 4”. The relative terminology may refer to plus or minus a percentage (e.g., 1%, 5%, 10%, or more) of an indicated value.

It should be understood that although certain drawings illustrate hardware and software located within particular devices, these depictions are for illustrative purposes only. Functionality described herein as being performed by one component may be performed by multiple components in a distributed manner. Likewise, functionality performed by multiple components may be consolidated and performed by a single component. In some embodiments, the illustrated components may be combined or divided into separate software, firmware and/or hardware. For example, instead of being located within and performed by a single electronic processor, logic and processing may be distributed among multiple electronic processors. Regardless of how they are combined or divided, hardware and software components may be located on the same computing device or may be distributed among different computing devices connected by one or more networks or other suitable communication links. Similarly, a component described as performing particular functionality may also perform additional functionality not described herein. For example, a device or structure that is “configured” in a certain way is configured in at least that way but may also be configured in ways that are not explicitly listed.

For ease of description, some or all of the example systems presented herein are illustrated with a single exemplar of each of its component parts. Some examples may not describe or illustrate all components of the systems. Other examples may include more or fewer of each of the illustrated components, may combine some components, or may include additional or alternative components.

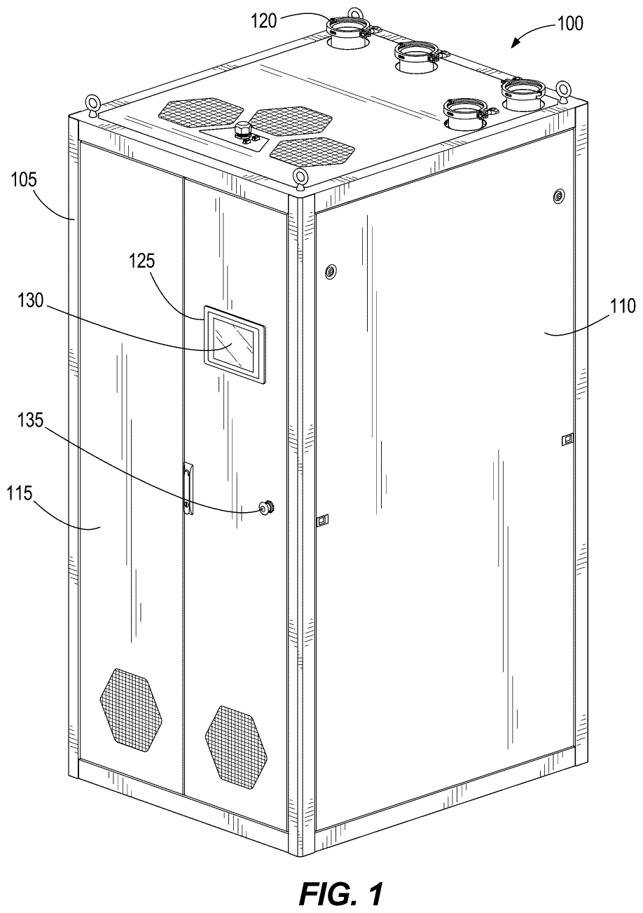

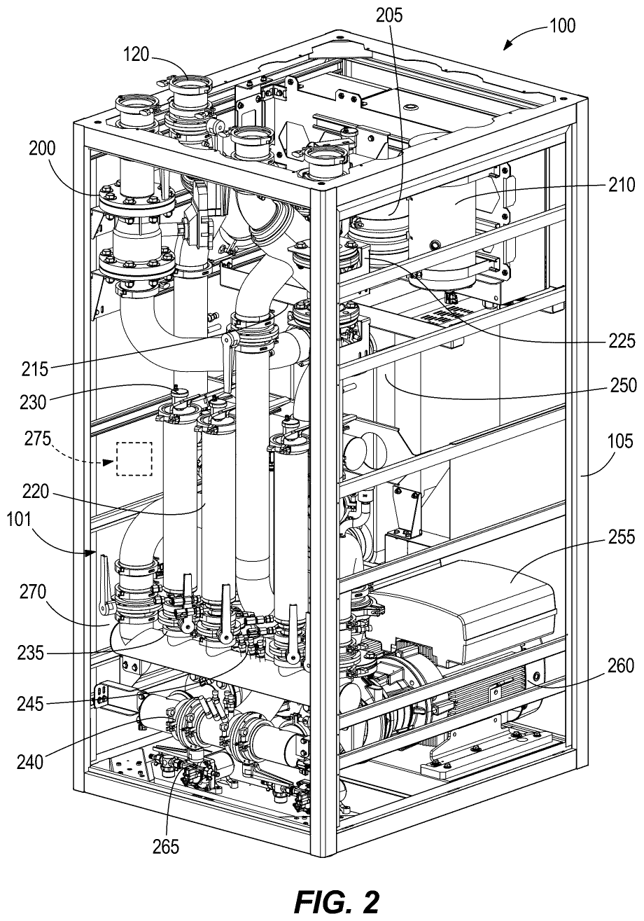

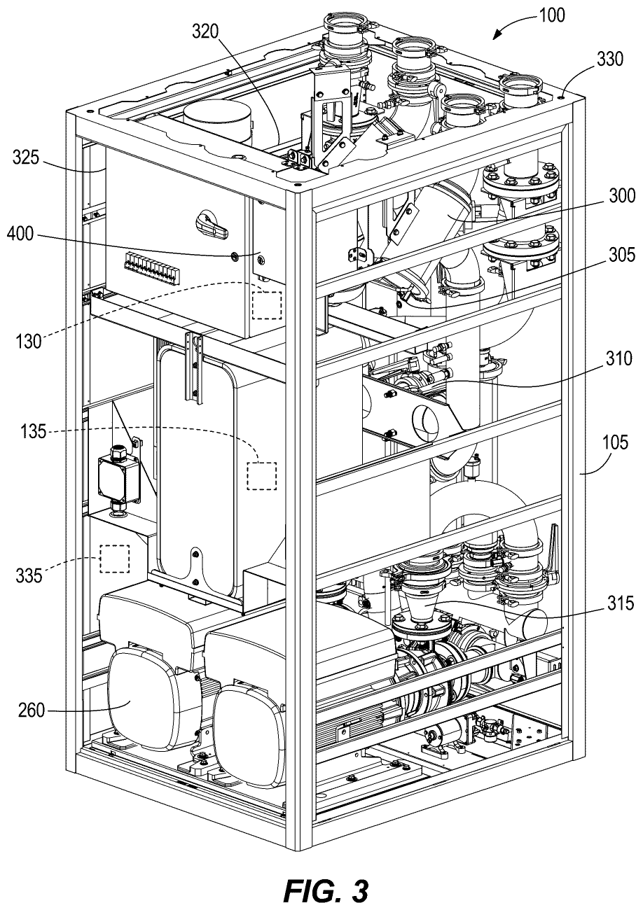

FIG. 1 is an illustration of a coolant distribution unit (CDU) 100 that includes a housing 105 (also referred to as a cabinet, rack, caster, or frame), the housing 105 having walls 110 and doors 115. The doors 115 open outwardly, allowing access to the internal elements of the CDU 100, shown in greater detail in FIGS. 2-3. The housing 105 also includes a pipe interface 120 for connecting the CDU 100 to a coolant pipe network. The coolant pipe network may be integrally formed within a building, such as a data center, and/or arranged modularly to connect to servers or other electronic equipment to provide fluid for cooling. A human-machine interface (HMI) 125 is located on one of the doors 115 of the CDU 100.

The HMI 125 may include various inputs and outputs, such as a touchscreen for direct interaction, physical buttons or keypads for tactile control, or support for external keyboards and mice. In some instances, the HMI 125 may include a voice command interface, a barcode scanner, a RFID reader, or biometric inputs such as fingerprint or retinal scans to facilitate access authorization.

The HMI 125 also includes display screen 130 for displaying information. In some instances, the HMI 125 also includes status indicator lights or speakers for sounding an audible status, such as an alarm or fault detection warning. In some instances, the HMI 125 also includes a light projection element for projecting an image or a light onto a ceiling and/or floor. For instance, the HMI 125 may project a different color light onto the ceiling indicating a status condition for the CDU 100, such as, for example, a green light for operational, a yellow light for a service request, and a red light for not operational. The CDU 100 also includes a shut-off button 135 for initiating an emergency shut down of the CDU 100.

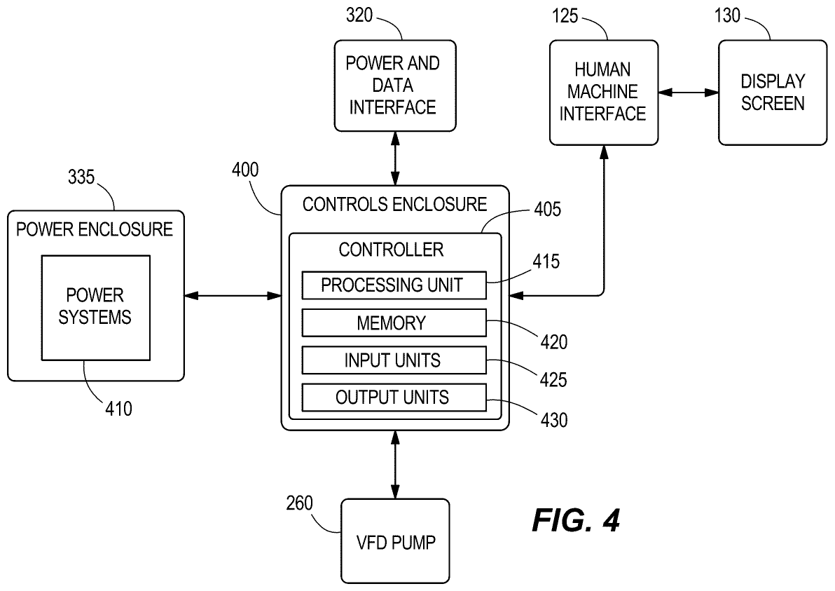

Referring now to FIG. 2 and FIG. 3 are the internal elements of the CDU 100 that together form a CDU pipe network 101 that conveys one or more coolants through the CDU 100 and to the pipe network. The CDU 100 includes a primary control valve 200 used to control the flow of coolant within the pipe network, along with expansion tanks 205 and reservoir 210 for storing the coolant fluid distributed throughout the pipe network. Primary strainer 300 and secondary strainer 215 capture and remove solid particles, debris, and contaminants from the coolant as it circulates through the system. The primary strainer 300 is attached to a removable filter 305 for easy discard of such captured contaminants. The CDU 100 also includes secondary filters 220 for redundant filtration. Primary flow meter 310 and secondary flow meter 225 are used to measure the rate at which coolant is flowing through the system. The measured flow rate information is transmitted to a controller 405 (See FIG. 4) and may be displayed on the screen 130.

The CDU 100 further includes an automatic air vent 230 to continuously remove air and other gases that accumulate in the coolant system. Isolation valve 235 allows specific sections of the cooling system to be isolated from the rest, providing access for maintenance, repairs, and system modifications. Temperature sensors 240 measure the temperature of the coolant at various points within the CDU 100, and pressure sensors 245 monitor the pressure within the pipe network. Both the temperature sensors 240 and the pressure sensors 245 generate and output data which is sent to the controller 405. In some instances, additional sensors are located within the CDU 100. For example, in the present embodiment, a water quality sensor 270 continuously monitors various parameters of the coolant, such as pH levels, particulate matter, and conductivity. In other embodiments, the water quality sensor may monitor corrosion inhibitors, dissolved oxygen content, and the presence of contaminants, such as biological organisms. The data regarding the quality of the water is transmitted to the controller 405, which is configured to control the injection of additives and/or an additive solution to correct any water quality imbalance. In the present embodiment, the water quality sensor is located within the CDU. In other embodiments, the water quality sensor 270, and other sensors, may be located in a separate unit from the from the CDU located elsewhere in a facility in which the CDU is located. The water quality sensor 270 would be fluidly coupled to the CDU. In other embodiments, the water quality sensor 270 and other sensors would be incorporated in a separate, enclosure that is removably fluidly coupled to the CDU.

Additionally, the water quality sensor 270 may be configured to track the operational duration of the CDU 100. Based on either the measured water quality parameters or at predetermined time intervals, the controller 405 may trigger operation of an injection system 275. The injection system 275 introduces precise amounts of additives, such as chemicals or biocides, into the coolant. The additives maintain optimal coolant conditions, preventing issues like corrosion or microbial growth, and ensure efficient and timely treatment based on actual system needs or scheduled maintenance protocols. In some examples, the injection system 275 may be triggered by an input on the HMI 125.

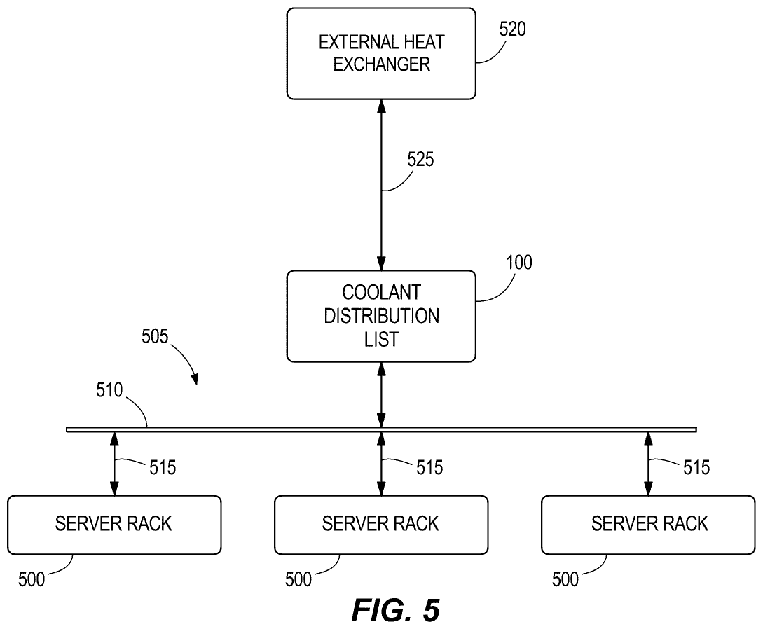

The CDU 100 also includes a heat exchanger 250 is facilitates the transfer of heat from the coolant fluid to another fluid without mixing the fluids. For instance, in the CDU 100, the heat exchanger 250 transfers heat from the warm coolant returning from the data center equipment to a chilled water loop or a refrigerant system. Further details regarding the heat exchange are provided in FIG. 5.

The CDU 100 also includes one or more pumps 260 (e.g., two pumps) that are each controlled by a variable frequency drive (“VFD”) 255. The VFD 255 controls the flow of the coolant fluid by adjusting the speed of the pump 260 to match the actual cooling demand of the system. The pumps may be operated simultaneously. In other instances, the pumps may be operated in a configuration in which one pump is generating the entire flow of coolant to the system while the second pump is not operating, but instead provides a backup in case the pump 260 fails or faults, ensuring continuous cooling. In some instances, the pumps 260 are replaceable. A pump check valve 315 is connected to each pump 260 to prevent the reversal of coolant flow when the pump is not operating. Fill/make-up pump 265 allows for the initial filling of the entire cooling system with coolant when it's first installed, or after maintenance that requires draining of the coolant fluid.

The CDU 100 includes a power and data interface, which provides power and data communications to the power enclosure 325 and the controls enclosure 400. In some instances, the housing 105 includes lifting eyes 330 that allow the attachment of cables or clips to lift the CDU 100, allowing for quick installation, servicing, or removal.

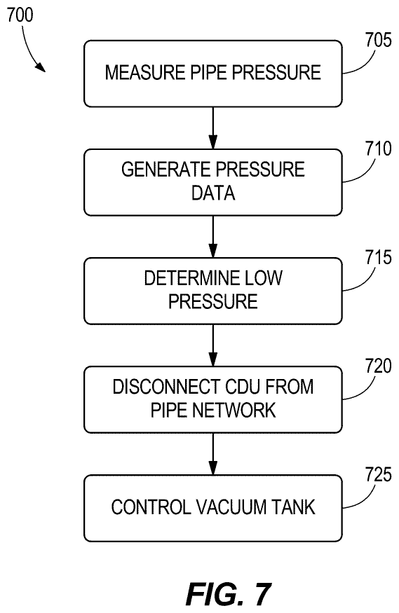

FIG. 4 is a schematic system diagram of the CDU 100. As previously described, the CDU 100 includes a HMI 125 with a screen 130, a power enclosure 325, a controls enclosure 400, a power and data interface 320, and a pump 260. In some instances, additional pumps, such as the secondary pump 260, are similarly connected. The power enclosure 325 houses the power systems 410 that power the various electronic elements within the CDU 100, such as the temperature and pressure sensors, control valves, pumps, and controller. The CDU 100 additionally includes a vacuum tank 335 coupled to the pipe network to assist with control of the pressure of the coolant within the pipe network. The control of the vacuum tank 335 is described in greater detail in FIG. 7.

In some examples, a leak sensor (or multiple leak sensors) is included to monitor and detect leaks within the pipe network or within elements of the CDU 100. The leak sensor may be located within or near the vacuum tank 335 or may fit together with an auto-top feed shutoff portion of the vacuum tank 335. In some instances, the leak sensor works in conjunction with the pressure sensor 245. In one embodiment, the pressure sensor 245 is the leak sensor and detects a rapid drop in pressure. The controller 405 monitors pressure in the pipe network with one or more of the pressure sensors 245, and monitors for a rapid change in pressure at one location with little/no change in pressure at another location. In the event that a leak is detected and/or determined, the controller 405 controls the pumps to reduce, slow, or stop the leak. The controller 405 may take other actions, including auto top feed shutoff, actuating a vacuum depressurization valve to open a valve to a depressurization tank, or the like.

The leak sensor may be, for example, a leak sensor wire or a leak sensor cage. In instances where the leak sensor is a leak sensor wire, the sensor may be positioned within or around the CDU 100, or may be positioned along the pipe network or near servers connected to the pipe network.

The controls enclosure 400 houses the controller 405, which includes a plurality of electrical and electronic components that distribute power, provide operational control, and enable protection to the components and modules within the controller 405 or within the CDU 100. For example, the controller 405 includes, among other things, a processing unit 415 (e.g., an electronic processor, a microprocessor, a microcontroller, or another suitable programmable device), a memory 420, input units 425, and output units 430. The processing unit 415 is implemented using a known computer architecture, such as a modified Harvard architecture, a von Neumann architecture, etc. The processing unit 415, the memory 420, the input units 425, and the output units 430, as well as the various modules connected to the controller 405 are connected by one or more control and/or data buses. The use of one or more control and/or data buses for the interconnection between and communication among the various modules and components would be known to a person skilled in the art in view of the invention described herein. In some embodiments, the controller 405 is implemented partially or entirely on a semiconductor (e.g., a field-programmable gate array [“FPGA”] semiconductor) chip, such as a chip developed through a register transfer level (“RTL”) design process.

The memory 420 is a non-transitory computer readable medium that includes, for example, a program storage area and a data storage area. The program storage area and the data storage area can include combinations of different types of memory, such as read-only memory (“ROM”), random access memory (“RAM”) (e.g., dynamic RAM [“DRAM”], synchronous DRAM [“SDRAM”], etc.), electrically erasable programmable read-only memory (“EEPROM”), flash memory, a hard disk, an SD card, or other suitable magnetic, optical, physical, or electronic memory devices. The processing unit 415 is connected to the memory 420 and executes software instructions that are capable of being stored in a RAM of the memory 420 (e.g., during execution), a ROM of the memory 420 (e.g., on a generally permanent basis), or another non-transitory computer readable medium such as another memory or a disc. Software included in the implementation of the CDU 100 can be stored in the memory 420 of the controller 405. The software includes, for example, firmware, one or more applications, program data, filters, rules, one or more program modules, and other executable instructions. In other constructions, the controller 405 includes additional, fewer, or different components.

FIG. 5 is an illustration of the CDU 100 in combination with servers of a data center. The CDU 100 is connected to one or more server racks 500 via a pipe network 505. From the CDU 100, large diameter supply pipes carry chilled coolant fluid. A main supply line 510 branch into smaller secondary pipes 515 that run along rows of the server racks 500. Each of the secondary pipes 515 connects with an individual server rack. After absorbing heat from the server racks, the warmed coolant is collected by a similar network of return pipes. These return pipes gradually merge into larger diameter pipes as they transport the heated coolant back to the CDU 100 for re-cooling and recirculation. In some examples, one or more additional CDUs 100 are connected to the pipe network.

In some instances, the CDU 100 is also connected to an external heat exchanger 520 via a secondary pipe network 525. Warm coolant from the pipe network 505 enters the CDU 100, and the CDU 100 transfers heat to the secondary pipe network 525 via the heat exchanger 250. The heated fluid in the secondary loop is then pumped to the external heat exchanger 520. After releasing its heat to the external environment, the cooled fluid returns to the CDU 100.

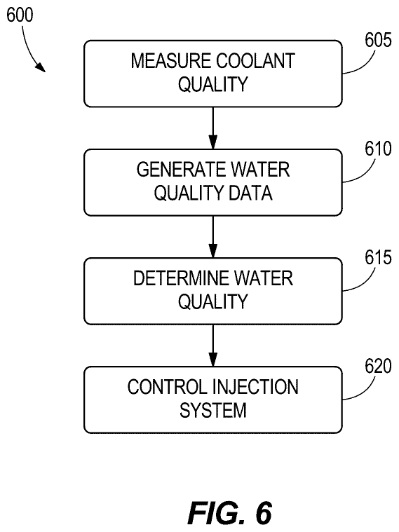

FIG. 6 is a flow chart of a process 600 of measuring fluid quality of the CDU 100. As previously described, the quality of the fluid may directly impact the efficiency of the cooling. Accordingly, the CDU 100 advantageously measures the fluid quality for unwanted substances and provides additives to counteract and remove the unwanted substances. The process 600 may be performed by the controller 405 (e.g., via the processing unit 415) automatically or in response to an input received via the HMI 125. The process 600 includes step 605, where the coolant quality is measured by the water quality sensor 270. The water quality sensor 270 may use electrochemical, optical, or spectroscopic methods to measure different parameters. For instance, a pH element within the water quality sensor 270 may include ion-selective electrodes to measure hydrogen ion concentration, while conductivity element within the water quality sensor 270 may detect the presence of dissolved ions that can indicate chemical buildup. An optical element within the water quality sensor 270 may use UV-Vis spectroscopy to detect organic compounds or microorganisms, and a fluorescence element within the water quality sensor 270 may identify specific biological markers and/or biological material.

The water quality sensor 270 then generates data, at step 610, the data including the various parameters or characteristics detected within the coolant, and transmits the data to the controller 405. The controller 405 then determines, at step 615, the quality of the water using these parameters or characteristics. The controller 405 then compares the measured parameters to a number of threshold values, and optionally performs a trend analysis of the water quality. For instance, the pH levels may be compared to a predetermined range indicating an acceptable level of acidity or basicity for the coolant fluid. The trend analysis may provide an indication that the coolant will stabilize over time or if additives are needed to correct the coolant quality. Similarly, the controller 405 analyzes the conductivity to detect any unusual ionic content that could indicate chemical buildup or contamination. The controller 405 also assess biocide levels by measuring chemical markers for biological identifiers and/or by analyzing the data from the water quality sensor 270 that indicates biological activity. Particulate measurements may be correlated with system runtime to identify any abnormal accumulation of debris. It should be understood that the steps of the process 600 may be performed in any order. For example, the controller 405 may compare the measured parameters to a number of threshold values, or optionally performs a trend analysis of the water quality, before determining the quality of the water using various water parameters or characteristics.

In some instances, the controller 405 runs algorithms stored in the memory 420 that compares the different parameters within the data, such as how pH may affect the efficacy of certain biocides, or how temperature influences chemical reaction rates. When the controller 405 has determined that the quality of the fluid requires correction, the controller 405 activates and controls the injection system 275, at step 620, to provide an additive to the coolant to counteract the identified imbalance. For instance, biocides may be added to the coolant to prevent the growth of microorganisms like algae, bacteria, and fungi. These biocides may be, for example, oxidizing agents such as chlorine or bromine compounds, or non-oxidizing biocides like isothiazolones or quaternary ammonium compounds. To combat scale formation and mineral deposits, the injection system 275 may add scale inhibitors like phosphonates or polycarboxylates to the coolant. Corrosion inhibitors, such as azoles for copper protection or molybdates for ferrous metals, may be added by the injection system 275 to prevent deterioration of metal components in the system. The injection system 275 may add pH adjusters, like sodium hydroxide or sulfuric acid, to maintain the coolant within an optimal pH range, for example, between 7 and 9, to minimize corrosion and optimize the effectiveness of other additives.

The injection system 275 may add oxygen scavengers, such as sodium sulfite, to reduce dissolved oxygen levels and further prevent corrosion within the pipe network 505. In some examples, a pipe network may need freeze protection, and the injection system 275 may provide a glycol-based additive. In some examples, the injection system 275 adds dispersants or surfactants to keep particulates suspended in the coolant, preventing them from settling and forming deposits. These suspended particulates are then more easily captured by the primary strainer 300 and secondary strainer 215 or by the filters 305, 220. The specific combination and concentration of additives provided by the injection system 275 is controlled by the CDU 100 based on real-time sensor data. In some instances, the additives and thresholds are set via the HMI 125.

FIG. 7 is a flow chart of a process 700 of responding to a low-pressure event within the CDU 100. As previously described, the CDU 100 includes a vacuum tank 335 coupled to the pipe network 505. In the event of a leak of coolant from the pipe network 505, the controller 405 is configured to activate the vacuum tank 335, creating a negative pressure and preventing the leak of coolant. The process 700 includes step 705, where the pressure within a pipe of the pipe network 505 is measured by one or more of the pressure sensors 245.

The pressure sensor then generates data, at step 710, including the overall pressure level of the coolant fluid within the pipe network 505. These data are then transmitted to the controller 405, which analyzes this pressure data, comparing the measured pressure level to a predetermined thresholds and/or a historical trend. If the controller 405 determines that the pressure level is below the predetermined threshold or shows an abnormal rate of decline (e.g., the speed at which the pressure drops exceeds a threshold), at step 715, the controller 405 interprets this as a leak of the coolant fluid from the pipe network 505.

In response to the determination, the controller 405 shuts off the pump 260 to stop actively pushing coolant through the system. The controller 405 then isolates the CDU 100 from the pipe network 505 at step 720, preventing gravity-driven coolant loss from the larger system. In some instances, the disconnection of the CDU 100 from the pipe network 505 is performed by closing a valve that connects the CDU 100 to the pipe network 505. The controller 405 then connects the vacuum tank 335 to the pipe network 505, at step 725, preventing gravity-driven coolant loss from the pipe network 505. The vacuum tank 335 is configured to be maintained at negative pressure, which creates a suction effect that pulls coolant away from the leak point and towards the tank. By reversing the pressure gradient within the pipe network 505, the amount of coolant that can escape through the leak is reduced.

The pressure sensors 245 continue to monitor the system during this process 700, allowing the controller 405 disconnect the vacuum tank 335 and reconnect the CDU 100 to the pipe network 505 when the pressure levels return to optimal levels (e.g., are determined to be above the predetermined threshold). This process 700 allows for maintenance personnel to respond and repair the leak before a substantial volume of coolant is lost, thereby minimizing potential damage and reducing system downtime.

The process 700 may be similarly performed using a leak sensor. For example, instead of measuring a pressure of the pipe network 505 via a pressure sensor 245, a leak sensor wire may be used to detect coolant leaks from the pipe network 505. When the controller 405 determines that a coolant leak exists within the pipe network 505, the controller 405 similarly performs the process 700 of closing the valve that connects the CDU 100 to the pipe network 505 and connecting the vacuum tank 335 to the pipe network 505. Additionally, the process 700 may be similarly performed using a combination of sensors, such as both the pressure sensor 245 and the leak sensor wire.

Thus, aspects herein provide, among other things, systems and methods for system interventions for coolant distribution units.

What is claimed is:

1. A method of monitoring water quality of a coolant distribution system, the method comprising:
measuring, via a sensor, a characteristic of water within a pipe of the coolant distribution system;
generating, via the sensor, data indicating a quality of the water within the pipe based on the characteristic;
determining, via an electronic processor, that the quality of the water within the pipe is below a predetermined threshold; and
controlling, via the electronic processor, an injection system to inject an additive solution to the water in the pipe in response to the quality of the water within the pipe being below the predetermined threshold.

2. The method of claim 1, wherein the characteristic of the water within the pipe includes a measurement of a biological material within the water.

3. The method of claim 2, wherein the additive solution includes a biocide configured to reduce the biological material within the water.

4. The method of claim 1, wherein the characteristic of the water within the pipe includes a measurement of a mineral within the water.

5. The method of claim 4, wherein the additive solution includes a chemical configured to reduce a buildup of the mineral within the water.

6. The method of claim 1, wherein the characteristic of the water within the pipe includes a measurement of a dissolved oxygen within the water.

7. The method of claim 6, wherein the additive solution includes an oxygen scavenger configured to reduce the dissolved oxygen.

8. A method of controlling a coolant distribution system connected to a pipe network, the method comprising:
measuring, via a sensor, a coolant leak condition of the coolant distribution system;
generating, via the sensor, data indicating the coolant leak condition;
determining, via an electronic processor, that a coolant leak exists within the coolant distribution system in response to the data;
controlling, via the electronic processor, one or more components of the coolant distribution system.

9. The method of claim 8, wherein the sensor is a leak sensor wire.

10. The method of claim 8, wherein the sensor is a leak sensor cage.

11. The method of claim 8, wherein the sensor is a pressure sensor.

12. The method of claim 8, wherein the electronic processor determines that a coolant leak exists based on a rapid change in a pressure at a location within the coolant distribution system.

13. The method of claim 8, wherein the electronic processor controls a pipe of the coolant distribution system in response to the coolant leak by disconnecting a pipe from the pipe network.

14. The method of claim 8, wherein the electronic processor controls a valve of a vacuum tank to generate a negative pressure within a pipe of the pipe network.

15. The method of claim 8, wherein the electronic processor controls a pump of the coolant distribution system to reduce, slow, or stop the coolant leak.

16. A coolant distribution unit comprising:
a housing;
a coolant distribution unit pipe network including one or more pipes at least partially supported in the housing and configured to convey a coolant, the coolant distribution unit pipe network fluidly coupled to a building pipe network, the coolant distribution unit pipe network including one or more leak detection sensors configured to measure a coolant leak condition;
an injection system fluidly coupled to the coolant distribution unit pipe network, the injection system configured to inject an additive solution to the coolant in a pipe; and
an electronic processor supported in the housing and configured to control operation of one or more elements of the coolant distribution unit pipe network,
wherein the electronic processor is configured to determine whether a leak has occurred in a pipe of the building pipe network, and
wherein the electronic processor is configured to determine a quality of a coolant with the pipe network and control the injection system to inject an additive solution.

17. The coolant distribution unit of claim 16, wherein the quality of the coolant is one of a measurement of a biological material, a measurement of a mineral, and a measurement of a dissolved oxygen.

18. The coolant distribution unit of claim 16, wherein the additive solution is one of a biocide and a chemical configured to reduce a buildup of a mineral in the coolant.

19. The coolant distribution unit of claim 16, wherein the injection system is supported in the housing.

20. The coolant distribution unit of claim 16, wherein the electronic processor determines whether the leak occurred by monitoring a pressure within the building pipe network.
